(19) United States
(12) Patent Application Publication
(10) Pub. No.: US 2013/0140662 A1
(43) Pub. Date: Jun. 6, 2013

(54) PHOTODIODE DEVICE FOR IMPROVING THE DETECTIVITY AND THE FORMING METHOD THEREOF

(71) Applicants: Fang-Chung Chen, Nantou County (TW); Shu-Cheng Lin, Taipei City (TW)

(72) Inventors: Fang-Chung Chen, Nantou County (TW); Shu-Cheng Lin, Taipei City (TW)

(73) Assignee: National Chiao Tung University, Hsinchu City (TW)

(21) Appl. No.: 13/466,263

(22) Filed: May 8, 2012

(30) Foreign Application Priority Data
Dec. 6, 2011 (TW) 100144798

(51) Int. Cl. H01L 27/14; H01L 31/18

(52) U.S. Cl. 257/431; 438/57; 257/E27.122; 257/E31.126

(57) ABSTRACT

A method for forming the photodiode device is provided. The method comprises providing a substrate, then a transparent conductive film is formed on the substrate. A conductive polymer is formed on the transparent conductive film. A photoactive layer is formed on the conductive polymer. A charge blocking layer is formed on the photoactive layer. Finally, a cathode metal is formed on the charge blocking layer.

### BACKGROUND OF THE INVENTION

1. Field of the Invention

The invention relates to a photodiode device and the forming method thereof, particularly to the photodiode device for improving the detectivity.

2. Description of the Prior Art

The photodiode device can be divided into the inorganic photodiode device and the organic photodiode device due to the use of different materials. The inorganic photodiode device has already been applied in various fields extensively, such as charge-coupled devices (CCDs), complementary metal oxide semiconductors (CMOS) etc. Compared to the inorganic photodiode devices, organic photodiode devices have better characteristics, such as flexibility, lower processing temperature etc.

During the development of organic photodiode devices, a paper published in Nature Nanotechnology by Y. Yang et al. of University of California was received much attention recently [H. Y. Chen, M. K. F. Lo, G. Yang, H. G. Monbouquette, and Y. Yang, Nature Nanotech. 3, 54 (2008)]. The authors used the P3HT:PCBM polymer blends doped with inorganic nanoparticles (CdTe) as the active materials to make the organic photodiode devices. This paper pointed out that when CdTe was doped into the active layer of the device, the external quantum efficiency (EQE) can be improved and a high photoconductive gain can be obtained.

In 2010, the applicant of this case had doped near-infrared materials into the active layer to obtain high photoconductive gains [F. C. Chen, S. C. Chien and G. L. Cious, Appl. Phys. Lett., 97, 103301 (2010)]. Because the organic near-infrared materials were doped, the application range of the photodiode device could be extended to the wavelength (750 nm˜950 nm) of near-infrared effectively. More importantly, the applicant used the organic dye molecule instead of the inorganic nanoparticles. The use of organic materials has the following advantages: 1. A lot of organic dye molecules with long-wavelength absorption are available at present. Their diversified chemical structures are favorable to the improvement of the device performance in the future, which has an opportunity to be extended to even longer wavelength range, too. 2. According to the past experience, it is necessary to consider the phase separation problem for the device made up of organic and inorganic mixtures. Although there might be still phase separation phenomenon for the use of organic dye molecule, but the degree phase separation problem is relatively lower, and the efficiency of the device will be better. 3. Organic molecules have lower toxicity compared to most semiconducting inorganic nanoparticle. The main problem of such device, however, is their higher leakage current because of the low energy gap of the organic dye. The high leakage current usually results in a low detectivity.

In 2011, G. Sarasqueta et al. utilized the organic/inorganic blocking layer to reduce the dark current of the organic/inorganic mixed photodiode device, so as to improve the device detectivity [G. Sarasqueta, K. R. Chiudhury, J. Subbiah and F. So, Adv. Funct. Mat. 21, 167 (2011)]. However, this device does not have any photoconductive gain, and the amplifying effect of the signal is relatively poor.

### SUMMARY OF THE INVENTION

According to prior art, because the operation mechanism of organic photoconductive gain device is different from that of the common photodiodes, it is still unknown whether the charge blocking layer is able to improve the device detectivity. Thus, this application case provides a new solution, which can obviously improve the dark current of the device, and further improve the detectivity of organic photodetectors exhibiting photoconductive gains. From the results of the above-mentioned work by H. Y. Chen et al., we can realize that the photoconductive gain phenomenon of organic photodiode devices could be achieved easily and high photoconductive gains could be obtained, but after the near-infrared molecule was added into the device, very large dark current might be generated due to its low energy gap. As a result, the improvement for the detectivity of these devices would be quite difficult. Thus, it is necessary to find an effective method for reducing the dark current of organic photodiodes with photoconductive gains.

Therefore, the main purposes of the invention are to disclose a charge blocking layer for reducing the dark current of the photodiode device, thereby improving the detectivity of the photodiode devices, and to maintain high responsivities and high external quantum efficiencies.

Another purpose of the invention is to replace present existing inorganic photodiode devices, in order to reduce the cost of products.

The other purpose of the invention is to apply the organic photodiode device in flexible electronic or display products such as photosensitive touching panels.

According to the above-mentioned purposes, the invention discloses a method for forming the photodiode device. The method comprises providing a substrate. A transparent conductive film is formed on the substrate. A conductive polymer is formed on the transparent conductive film. A photoactive layer is formed on the conductive polymer. A charge blocking layer is formed on the photoactive layer. Finally, a cathode metal is formed on the charge blocking layer.

In an embodiment of the invention, the above-mentioned method for forming the conductive polymer comprises the coating method.

In an embodiment of the invention, the above-mentioned method for forming the conductive polymer comprises the spin-coating method.

In an embodiment of the invention, the steps for forming the above-mentioned photoactive layer comprises providing the poly(3-hexylthiophene (P3HT) and [6,6]-phenyl C61-butyric acid methyl ester (PCBM); mixing the organic dye in P3HT and PCBM to form the organic mixture; and depositing the organic mixture to form a photoactive layer on the conductive polymer.

In an embodiment of the invention, the above-mentioned method for forming the cathode metal comprises the thermal evaporation method.

According to the method for forming the photodiode device, the invention discloses a photodiode device for improving the detectivity. The method comprises providing a substrate. A transparent conductive film is formed on the substrate. A conductive polymer is formed on the transparent conductive film. A photoactive layer is formed on the conductive polymer. A charge blocking layer is formed on the photoactive layer. Finally, a cathode metal is formed on the charge blocking layer.

In an embodiment of the invention, the material of the above-mentioned transparent conductive film is the indium tin oxide (ITO).

In an embodiment of the invention, the material of the above-mentioned photoactive layer comprises the poly(3-hexylthiophene (P3HT) and the [6,6]-phenyl C61-butyric acid methyl ester (PCBM) and the organic dye.

In an embodiment of the invention, the composition of the above-mentioned organic dye comprises the 4,5-benzoindotricarbocyanine (Ir-125).

In an embodiment of the invention, the material of the above-mentioned charge blocking layer comprises the 2,9-dimethyl-4,7-diphenyl-1,10-phenanthroline (BCP).

In an embodiment of the invention, the above-mentioned cathode metal comprises a cathode material and a wire, and the cathode material is connected to an external circuit by the wire.

In an embodiment of the invention, the above-mentioned cathode material is calcium.

In an embodiment of the invention, the above-mentioned cathode material is aluminum.

In order to understand the above-mentioned purposes, characteristics and advantages of present invention more obviously, the detailed explanation is described as follows with preferred embodiments and figures.

### BRIEF DESCRIPTION OF THE DRAWINGS

The foregoing aspects and many of the attendant advantages of this invention will become more readily appreciated as the same becomes better understood by reference to the following detailed descriptions, when taken in conjunction with the accompanying drawings, wherein:

FIG. 1 illustrates the cross-section diagram for a photodiode device in accordance with the technique disclosed in the invention;

FIG. 2 illustrates the energy level diagram for the internal material of photodiode device in accordance with the technique disclosed in the invention;

FIG. 3 illustrates the dark current diagram for a photodiode device after adding different thickness of charge blocking layer in accordance with the technique disclosed in the invention;

FIG. 4 illustrates the external quantum efficiency of the photodiode device under 0.2V bias in accordance with the technique disclosed in the invention; and

FIG. 5 illustrates the detectivity of the photodiode device under different thickness of charge blocking layer and different wavelengths in accordance with the technique disclosed in the invention.

### DESCRIPTION OF THE PREFERRED EMBODIMENT

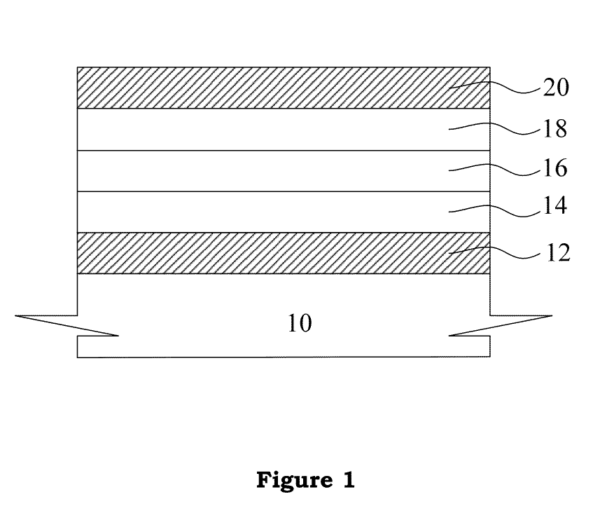

Firstly, please refer to FIG. 1. FIG. 1 illustrates a cross-section diagram of a photodiode device. The forming steps of the photodiode device 1 comprise providing a substrate 10. A transparent conductive film 12 is formed on the substrate 10, wherein the forming method comprises the sputtering, vapor coating, and chemical vapor deposition, and the thickness range of the transparent conductive film 12 is about 1˜100 nm. Then, a conductive polymer 14 is formed on the transparent conductive film 12, wherein the forming method comprises the coating and the spin-coating, the thickness range of the conductive polymer 14 is about 1˜1000 nm. A photoactive layer 16 (or organic semiconductor layer) is deposited on the conductive polymer 14, which comprises the poly(3-hexylthiophene (P3HT) and the [6,6]-phenyl C61-butyric acid methyl ester (PCBM) and the organic dye (Ir-125). A charge blocking layer 18 is formed on the photoactive layer 16 by the thermal evaporation. After annealing, a cathode metal 20 is formed on the charge blocking layer 18, wherein the cathode metal 20 is made up of a cathode material and a wire. The cathode material is generally the low work function metal, such as calcium, lithium etc., or the common metal oxide, such as Cs₂CO₃, TiOₓ, ZnO etc. The metal wire, such as gold, silver, copper, aluminum, nickel and zinc etc. is used to connect to the external circuit, and protect the cathode material from oxidized by the moisture in air. In this embodiment, the material of the transparent conductive film 12 comprises the indium tin oxide (ITO).

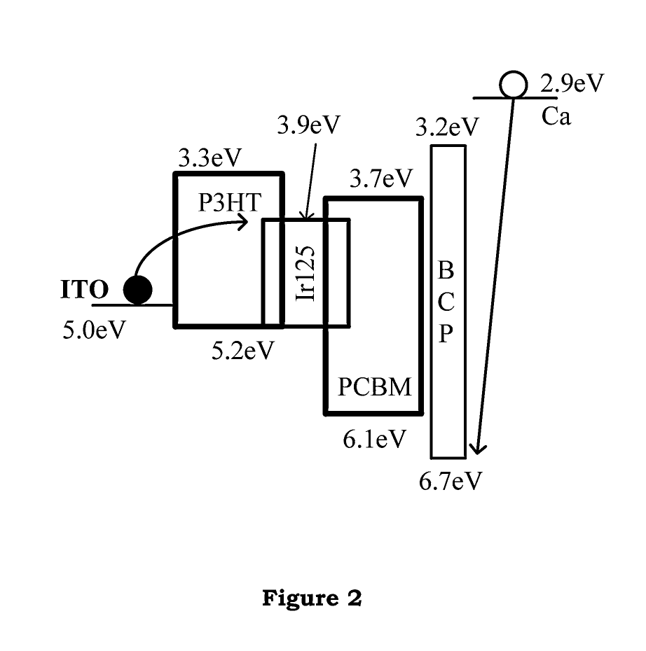

In an embodiment of the invention, due to the organic dye Ir-125 captures the electron carrier, thus the charge blocking layer 18 blocks the electric hole mainly. When the material of charge blocking layer 18 is 2,9-dimethyl-4,7-diphenyl-1,10-phenanthroline (BCP), the energy level of whole device is shown in FIG. 2.

As shown in FIG. 2, the operation mechanism of the photodiode device is shown as followings. After the device absorbs the photon and produces the separation of electron and electric hole, the electric hole can flow out the device smoothly under reverse bias, but can catch the electron in the potential energy well. Thus, when a large number of electrons are accumulated in the device, the strong electric field will be produced, so that the potential energy of holes will be reduced greatly under the reverse-bias conditions, thus holes can be injected into the device at large amount. Finally, they are received by the electrode to generate a large amount of current, and obtain the so-called photoconductive gain.

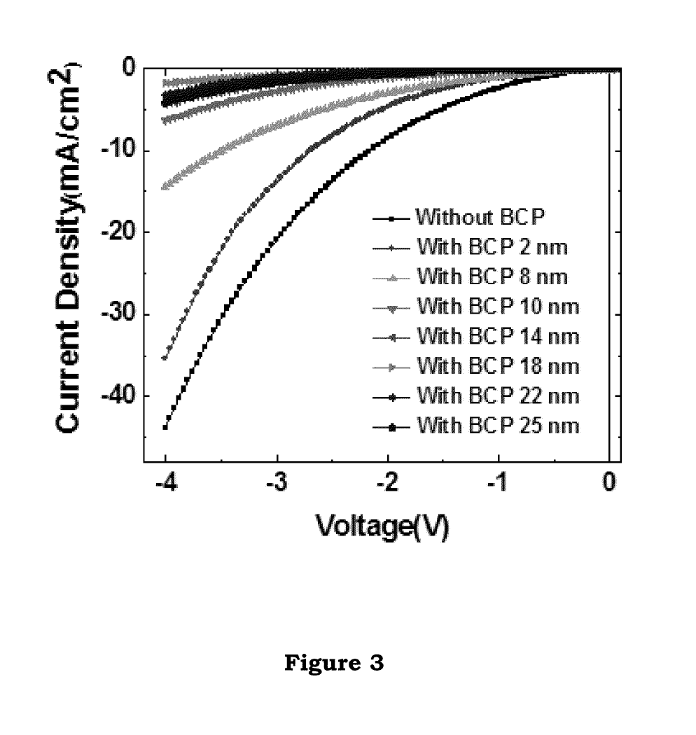

Then, please refer to FIG. 3. FIG. 3 illustrates the dark current diagram after the charge blocking layer 18 with different thickness is added into the photodiode device. It is very obvious that the charge blocking layer 18 can reduce the dark current of the device effectively. Meantime referring to the energy level shown in FIG. 2, holes have the opportunity to inject into the high occupied molecular orbital (HOMO) of P3HT or Ir-125 at the reverse bias. However, after the charge blocking layer 18 is added, it is expected that the injection of electric hole can be reduced greatly in accordance with the experiment. In addition, after injecting into the device, the probability for the collection of electron will be reduced too, thus the dark current of the whole device can be reduced.

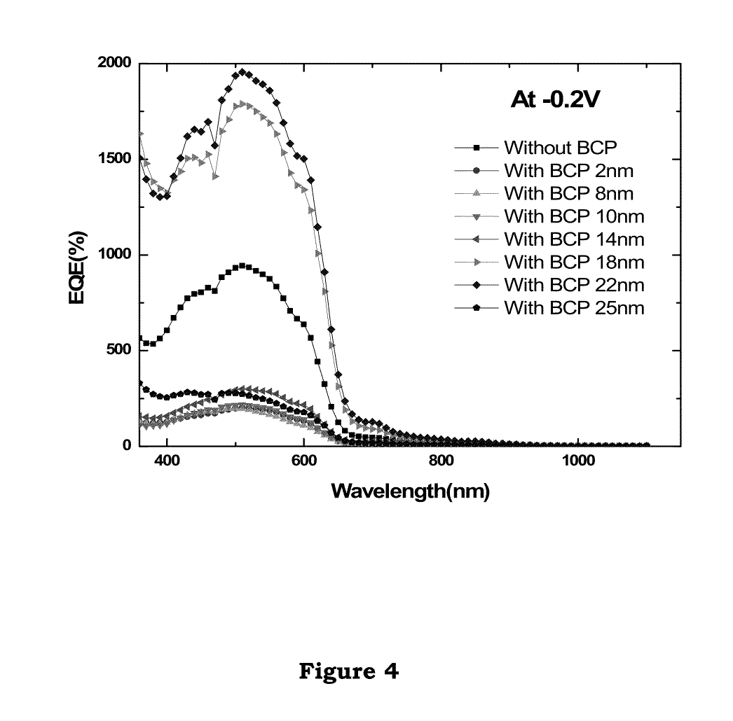

Then, please refer to FIG. 4 continuously. FIG. 4 shows the external quantum efficiency of the photodiode device under 0.2V bias. As shown in FIG. 4, when the thickness of charge blocking layer 18 is 22 nm, the highest external quantum efficiency of the device can be up to 2000%.

In addition, the external quantum efficiency is a very important figure of merit for the photodiode device theoretically. Another important figure of merit in practical application is the detectivity, wherein the definition of detectivity is:

D*=(AΔf)^{0.5}/NEP (1)

Where is A the detection area of device in cm²; Δf is the frequency in Hz; NEP is the noise equivalent power. When the light hits the photodiode device, the generated current will comprises some noises, such as the dark current noise, Johnson noise and thermal fluctuation noise or flicker noise. General speaking, the dark current is the main source of noise, thus NEP can be represented as:

NEP=iₙ/R′iₙ=(2qI_{d}Δf) (2)

Where iₙ is the noise current, R is the responsivity. When the equation (2) is substituted into the equation (1), the following equation will be obtained:

D*=((AΔf)^{0.5}R/iₙ=R/(2qJ_{d})^{0.5}

Where the unit of R is A/W, and the unit of J_{d} is A cm⁻², thus the unit of D* is Hz^{0.5} cm/W and 1 Jones=1 Hz^{0.5} cm/W. It is known from this equation, if the dark current of device can be reduced and the light current can be increased simultaneously, the detectivity of the photodiode device will be able to be increased tremendously.

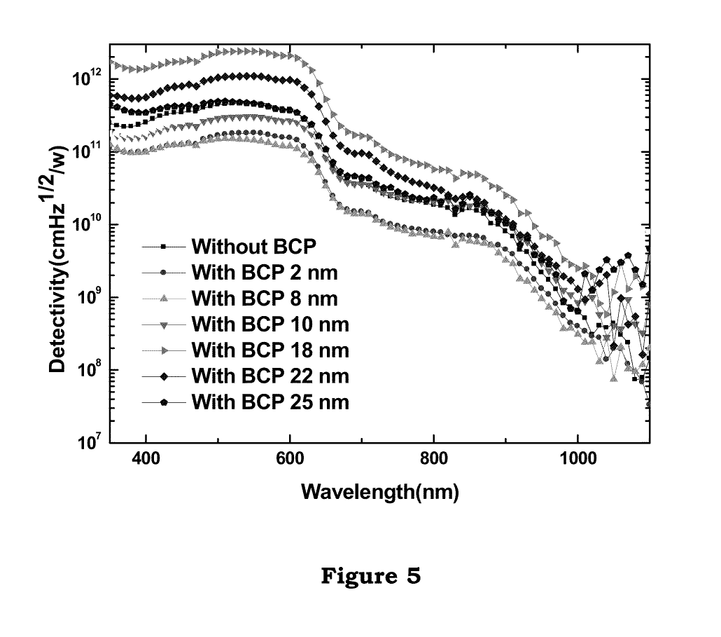

Then, please refer to FIG. 5. FIG. 5 shows the detectivity of the photodiode device made with different thicknesses of the charge blocking layer 18. When the thickness of charge blocking layer 18 is 18 nm and the wavelength is 550 nm, the detectivity of the device is 2.4×10¹² Jones (1 Jones=1 Hz^{0.5} cm/W), which has been improved significantly compared to the detectivity (4.5×10¹¹ Jones) of the device without the charge blocking layer 18. Thus, according to the above-mentioned results, after the use of the charge blocking layer 18, the detectivity of the organic photodiode device will be able to be increased tremendously. In addition, the dark current can be reduced from −43.8 to 1.82 mA/cm² under 4V of reverse bias. The detectivity of the organic photodiode device can be improved greatly due to the lower dark current at the same time.

It is understood that various other modifications will be apparent to and can be readily made by those skilled in the art without departing from the scope and spirit of this invention. Accordingly, it is not intended that the scope of the claims appended hereto be limited to the description as set forth herein, but rather that the claims be construed as encompassing all the features of patentable novelty that reside in the present invention, including all features that would be treated as equivalents thereof by those skilled in the art to which this invention pertains.

What is claimed is:

1. A method for forming the photodiode device, comprising:
providing a substrate;
forming a transparent conductive film on the substrate;
forming a conductive polymer on the transparent conductive film;
forming a photoactive layer on the conductive polymer;
forming a charge blocking layer on the photoactive layer; and
forming a cathode metal on the charge blocking layer to form the subject photodiode device.

2. The method according to claim 1, wherein the method for forming the conductive polymer comprises coating method.

3. The method according to claim 1, wherein the method for forming the conductive polymer comprises spin-coating method.

4. The method according to claim 1, wherein the steps for forming the above-mentioned photoactive layer comprise:
providing a poly(3-hexylthiophene (P3HT) and [6,6]-phenyl C61-butyric acid methyl ester (PCBM);
mixing an organic dye in the PCBM to form an organic mixture; and
depositing the organic mixture to form a photoactive layer on the conductive polymer.

5. The method according to claim 1, wherein the method for forming the charge blocking layer comprises thermal evaporation method.

6. A photodiode device for improving the detectivity, comprising:
a substrate;
a transparent conductive film being formed on the substrate;
a conductive polymer being formed on the transparent conductive film;
a photoactive layer being formed on the conductive polymer;
a charge blocking layer being formed on the photoactive layer; and
a cathode metal being formed on the charge blocking layer to form the subject photodiode device.

7. The device according to claim 6, wherein the material of the transparent conductive film is indium tin oxide (ITO).

8. The device according to claim 6, wherein a material of the photoactive layer is selected from the the group consisting of poly(3-hexylthiophene (P3HT) and the [6,6]-phenyl C61-butyric acid methyl ester (PCBM) and organic dye.

9. The device according to claim 8, wherein the composition of the organic dye comprises the Ir-125.

10. The device according to claim 6, wherein a material of the charge blocking layer comprises 2,9-dimethyl-4,7-diphenyl-1,10-phenanthroline (BCP).

11. The device according to claim 6, wherein a cathode metal comprises a cathode material and a wire, and the cathode material is connected electrically to an external circuit.

12. The device according to claim 11, wherein a material of cathode metal is selected from the group consisting of calcium, lithium, Cs₂CO₃, TiOₓ, and ZnO.

13. The device according to claim 11, wherein the wire is selected from the group consisting of gold, silver, copper, aluminum, nickel and zinc.
